(19) United States
(12) Patent Application Publication
(10) Pub. No.: US 2024/0047451 A1
(43) Pub. Date: Feb. 8, 2024

(54) NITRIDE-BASED SEMICONDUCTOR IC CHIP AND METHOD FOR MANUFACTURING THE SAME

(71) Applicant: INNOSCIENCE (SUZHOU) TECHNOLOGY CO., LTD., Suzhou City (CN)

(72) Inventors: Hui YAN, Suzhou City (CN); Sichao LI, Suzhou City (CN)

(21) Appl. No.: 17/626,117

(22) PCT Filed: Aug. 6, 2021
(86) PCT No.: PCT/CN2021/111294

§ 371 Date: Jan. 10, 2022

(51) Int. Cl. H01L 27/02; H01L 29/20; H01L 27/085; H01L 21/8252; H01L 21/76; H01L 29/417

(52) U.S. Cl. CPC H01L 27/0207; H01L 29/2003; H01L 27/085; H01L 21/8252; H01L 21/7605; H01L 29/4175; H01L 29/778

(57) ABSTRACT

A nitride-based semiconductor integrated circuit (IC) chip is provided. The IC chip comprises: a substrate; intra-transistor isolation regions formed in a surface of the substrate for defining power domains respectively for transistors integrated in the IC chip; an epitaxial body layer disposed over the substrate and the intra-transistor isolation regions; a first and a second nitride-based layers disposed above the epitaxial body layer. The epitaxial body layer and the substrate are formed of a same material and each of the one or more intra-transistor isolation regions is implanted to have a doping polarity opposite to a doping polarity of the substrate. By the implementation of the epitaxial body layer over the isolation regions, the quality of the heterojunction formed between the nitride-based semiconductor layers can be guaranteed as the impact of implantation of the isolation regions to the formation of heterojunction interface can be eliminated.

### FIELD OF THE INVENTION

The present invention generally relates to a semiconductor device. More specifically, the present invention relates to nitride-based semiconductor integrated circuit chip with substrate isolation structures for mitigating the back-gate effect.

### BACKGROUND OF THE INVENTION

In recent years, intense research on nitride-based, such as gallium nitride (GaN) based, high-electron-mobility transistors (HEMTs) has been prevalent, particularly for high power switching and high frequency applications. The nitride-based HEMT utilizes a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

Traditional nitride-based discrete devices need to be connected to Si driver ICs through PCBs or packages, which will introduce significant parasitic inductances, capacitances, and resistances to seriously affect high-frequency performance and occupy a large board area. The demand for monolithic integration of nitride-based IC and power devices is becoming more popular. For example, a half-bridge circuit, which is important in power conversion applications, may be formed by integrating two monolithic nitride-based power transistors, namely the higher side (HS) transistor and the lower side (LS) transistor on a Si substrate. The HS transistor may have a drain connected to VDD, and a source connected to a node SW, while the LS transistor may have a drain connected to node SW, and a source connected to GND.

One of the difficulties in integration of monolithic nitride-based semiconductor devices is the need for isolation between the devices to avoid back-gate effect. For example, if HS and LS transistors are not isolated, then HS substrate (sub) and LS substrate (sub) are connected through the entire Si substrate. If the entire substrate is connected to GND, then the HS sub will be at a negative potential relative to HS source when HS transistor is turned on. Due to the back gate effect, threshold voltage of HS transistor will increase, resulting in an increase in on-resistance. If the entire substrate is connected to the node SW, then the LS sub will be at a negative potential relative to the LS source when LS transistor is turned on. Due to the back gate effect, threshold voltage of LS transistor will increase, resulting in an increase in on-resistance. Increased on-resistance will increase switching and conduction losses, which will seriously affect power conversion efficiency.

Therefore, there is a need to have an improved device structure design and method to avoid the back gate effect in a half-bridge circuit formed with nitride-based transistors.

### SUMMARY OF THE INVENTION

In accordance with one aspect of the present disclosure, a nitride-based semiconductor integrated circuit (IC) chip including one or more transistors is provided. The IC chip comprises: a substrate; one or more intra-transistor isolation regions formed in a surface of the substrate for defining one or more power domains for the one or more transistors respectively; an epitaxial body layer disposed over the substrate and the one or more intra-transistor isolation regions; a first nitride-based layer disposed above the epitaxial body layer and a second nitride-based layer disposed on the first nitride-based epitaxial layer and having a bandgap greater than a bandgap of the first nitride-based epitaxial layer. The epitaxial body layer and the substrate are formed of a same material and each of the one or more intra-transistor isolation regions is implanted to have a doping polarity opposite to a doping polarity of the substrate.

The electrical isolation provided by the intra-transistor isolation regions permits independent control of the substrate or other materials under each transistor and/or under individual contacts within each power domain. Moreover, by the implementation of the epitaxial body layer over the isolation regions, the quality of the heterojunction formed between the nitride-based semiconductor layer can be guaranteed as the impact of implantation of the isolation regions to the formation of heterojunction interface can be eliminated.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIGS. 1 and 2 depict structure of an exemplary nitride-based semiconductor chip according to one embodiment of the present invention; FIG. 1 is a partial layout of the semiconductor chip showing a relationship among some elements and FIG. 2 is cross-sectional view taken along a line A-A′ in FIG. 1;

FIG. 3 depicts a variation of via configuration for the semiconductor chip of FIG. 1;

FIG. 4 depicts an exemplary semiconductor chip according to another embodiment of the present invention;

FIG. 5 depicts an exemplary semiconductor chip according to another embodiment of the present invention;

FIG. 6 depicts a circuit diagram of a half-bridge circuit according to one embodiment of the present invention;

FIGS. 7 and 8 depict structure of an exemplary semiconductor chip based on the half-bridge circuit of FIG. 6. FIG. 7 is a partial layout of the semiconductor chip and FIG. 8 is cross-sectional view taken along a line A-A′ in FIG. 7;

FIG. 9 depicts a variation of via configuration for the semiconductor chip of FIG. 7; and

FIGS. 10A-10F shows processes of a method for manufacturing a semiconductor chip according to the present invention.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

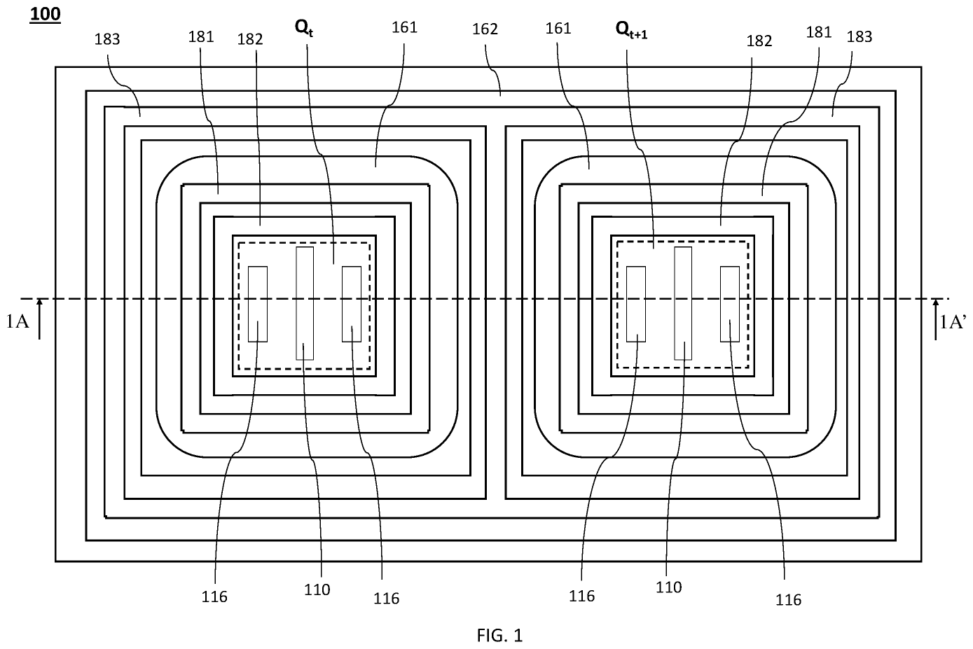

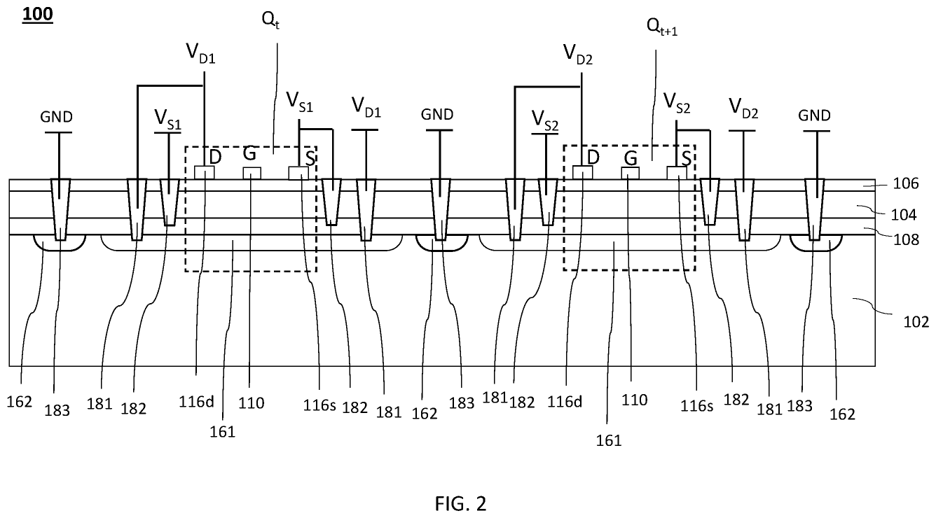

According to one aspect of the present invention, a plurality of transistors may be integrated into a single semiconductor chip in which a plurality of power domains is defined for providing isolation between the transistors. FIGS. 1 and 2 depict structure of a nitride-based semiconductor integrated circuit (IC) chip 100 including one or more transistors according to one embodiment of the present invention. For simplicity, only two transistors, Qₜ and Qₜ₊₁, are illustrated. FIG. 1 is a partial layout of the semiconductor chip 100 showing a relationship among some elements that constitute parts of the transistors Qₜ and Qₜ₊₁. FIG. 2 is cross-sectional view taken along a line A-A′ in FIG. 1.

Referring to FIGS. 1 and 2, the semiconductor chip 100 may include a substrate 102, an epitaxial body layer 108, a nitride-based semiconductor layer 104, a second nitride-based semiconductor layer 106, a plurality of gate electrodes 110, and a plurality of source/drain electrodes 116.

The substrate 102 may be a semiconductor substrate. The exemplary materials of the substrate 102 can include, for example but are not limited to, Si, p-doped Si, n-doped Si, or other suitable semiconductor materials.

The epitaxial body layer 108 may be disposed over the substrate 102. Preferably, the epitaxial body layer 108 and the substrate 102 are formed of a same material. The exemplary materials of the epitaxial body layer 108 can include, for example but are not limited to, Si, p-doped Si, n-doped Si, or other suitable semiconductor materials.

The nitride-based semiconductor layer 104 may be disposed over the epitaxial body layer 108. The exemplary materials of the nitride-based semiconductor layer 104 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1. The exemplary structures of the nitride-based semiconductor layer 104 can include, for example but are not limited to, multilayered structure, superlattice structure and composition-gradient structures.

The nitride-based semiconductor layer 106 may be disposed on the nitride-based semiconductor layer 104. The exemplary materials of the nitride-based semiconductor layer 106 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1.

The exemplary materials of the nitride-based semiconductor layers 104 and 106 are selected such that the nitride-based semiconductor layer 106 has a bandgap (i.e., forbidden band width) greater than a bandgap of the nitride-based semiconductor layer 104, which causes electron affinities thereof different from each other and forms a heterojunction therebetween. For example, when the nitride-based semiconductor layer 104 is an undoped GaN layer having a bandgap of approximately 3.4 eV, the nitride-based semiconductor layer 106 can be selected as an AlGaN layer having bandgap of approximately 4.0 eV. As such, the nitride-based semiconductor layers 104 and 106 can serve as a channel layer and a barrier layer, respectively. A triangular well potential is generated at a bonded interface between the channel and barrier layers, so that electrons accumulate in the triangular well potential, thereby generating a two-dimensional electron gas (2DEG) region adjacent to the heterojunction. Accordingly, the multi-channel switching device is available to include one or more GaN-based high-electron-mobility transistors (HEMT).

In some embodiments, the semiconductor chip 100 may further include a buffer layer and a nucleation layer (not illustrated), or a combination thereof. The buffer layer can be disposed between the epitaxial body layer 108 and the nitride-based semiconductor layer 104. The buffer layer can be configured to reduce lattice and thermal mismatches between the epitaxial body layer 108 and the nitride-based semiconductor layer 104, thereby curing defects due to the mismatches/difference. The buffer layer may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AlN, AlGaN, InAlGaN, or combinations thereof.

The nucleation layer may be formed between the epitaxial body layer 108 and the buffer layer. The nucleation layer can be configured to provide a transition to accommodate a mismatch/difference between the epitaxial body layer 108 and a III-nitride layer of the buffer layer. The exemplary material of the nucleation layer can include, for example but is not limited to AlN or any of its alloys.

The gate structures 110 may be disposed on/over/above the nitride-based semiconductor layer 106. In some embodiments, each of the gate structures 110 may include an optional gate semiconductor layer and a gate metal layer. The gate semiconductor layer and the gate metal layer are stacked on the nitride-based semiconductor layer 106. The gate semiconductor layer is between the nitride-based semiconductor layer 106 and the gate metal layer. The gate semiconductor layer and the gate metal layer may form a Schottky barrier. In some embodiments, the semiconductor chip 100 may further include an optional dielectric layer (not illustrated) between the p-type doped III-V compound semiconductor layer and the gate metal layer.

Specifically, the gate semiconductor layer may be a p-type doped III-V compound semiconductor layer. The p-type doped III-V compound semiconductor layer may create at least one p-n junction with the nitride-based semiconductor layer 106 to deplete the 2DEG region, such that at least one zone of the 2DEG region corresponding to a position below the corresponding gate structure 110 has different characteristics (e.g., different electron concentrations) than the rest of the 2DEG region and thus is blocked. Due to such mechanism, the transistors Qₜ and Qₜ₊₁ may have a normally-off characteristic for forming enhancement mode devices, which are in a normally-off state when their gate electrodes are at approximately zero bias. In other words, when no voltage is applied to the gate electrodes or a voltage applied to the gate electrodes is less than a threshold voltage (i.e., a minimum voltage required to form an inversion layer below the gate structures 110), the zone of the 2DEG region below the gate structures 110 is kept blocked, and thus no current flows therethrough. Moreover, by providing the p-type doped III-V compound semiconductor layers, gate leakage current is reduced and an increase in the threshold voltage during the off-state is achieved.

In some embodiments, the p-type doped III-V compound semiconductor layers can be omitted, such that the semiconductor chip 100 is a depletion-mode device, which means the transistors are in a normally-on state at zero gate-source voltage.

The exemplary materials of the p-type doped III-V compound semiconductor layers can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Mg, Zn, Cd, and Mg.

In some embodiments, the nitride-based semiconductor layer 104 includes undoped GaN and the nitride-based semiconductor layer 106 includes AlGaN, and the p-type doped III-V compound semiconductor layers are p-type GaN layers which can bend the underlying band structure upwards and to deplete the corresponding zone of the 2DEG region, so as to place the semiconductor chip 100 into an off-state condition.

In some embodiments, the gate electrodes may include metals or metal compounds. The gate electrodes may be formed as a single layer, or plural layers of the same or different compositions. The exemplary materials of the metals or metal compounds can include, for example but are not limited to, W, Au, Pd, Ti, Ta, Co, Ni, Pt, Mo, TiN, TaN, Si, metal alloys or compounds thereof, or other metallic compounds. In some embodiments, the exemplary materials of the gate electrodes may include, for example but are not limited to, nitrides, oxides, silicides, doped semiconductors, or combinations thereof.

In some embodiments, the optional dielectric layer can be formed by a single layer or more layers of dielectric materials. The exemplary dielectric materials can include, for example but are not limited to, one or more oxide layers, a SiOₓ layer, a SiNₓ layer, a high-k dielectric material (e.g., HfO₂, Al₂O₃, TiO₂, HfZrO, Ta₂O₃, HfSiO₄, ZrO₂, ZrSiO₂, etc), or combinations thereof.

The S/D electrodes 116 may be disposed on the nitride-based semiconductor layer 106. The “S/D” electrode means each of the S/D electrodes 116 can serve as a source electrode or a drain electrode, depending on the device design. The S/D electrodes 116 can be located at two opposite sides of the corresponding gate structure 110 although other configurations may be used, particularly when plural source, drain, or gate electrodes are employed in the device. Each of the gate structure 110 can be arranged such that each of the gate structure 110 is located between at least two of the S/D electrodes 116. The gate structures 110 and the S/D electrodes 116 can collectively act as at least one nitride-based/GaN-based HEMT with the 2DEG region.

In the exemplary illustration, for each of the transistors Qₜ and Qₜ₊₁, the adjacent S/D electrodes 116 are symmetrical about the gate structure 110 therebetween. In some embodiments, the adjacent S/D electrodes 116 can be optionally asymmetrical about the gate structure 110 therebetween. That is, one of the S/D electrodes 116 may be closer to the gate structure 110 than another one of the S/D electrodes 116.

In some embodiments, the S/D electrodes 116 can include, for example but are not limited to, metals, alloys, doped semiconductor materials (such as doped crystalline silicon), compounds such as silicides and nitrides, other conductor materials, or combinations thereof. The exemplary materials of the S/D electrodes 116 can include, for example but are not limited to, Ti, AlSi, TiN, or combinations thereof. The S/D electrodes 116 may be a single layer, or plural layers of the same or different composition. In some embodiments, the S/D electrodes 116 may form ohmic contacts with the nitride-based semiconductor layer 106. The ohmic contact can be achieved by applying Ti, Al, or other suitable materials to the S/D electrodes 116. In some embodiments, each of the S/D electrodes 116 is formed by at least one conformal layer and a conductive filling. The conformal layer can wrap the conductive filling. The exemplary materials of the conformal layer, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

The semiconductor chip 100 may further comprise intra-transistor isolation regions 161 formed in the substrate 102 and underneath the epitaxial body layer 108. Each intra-transistor isolation region 161 is disposed underneath a corresponding transistor to define a power domain for the transistor. Preferably, each intra-transistor isolation region 161 is implanted to have a doping polarity opposite to a doping polarity of the substrate 102.

The semiconductor chip 100 may further comprise intra-transistor conductive vias 181 extending from a top surface of the nitride-based epitaxial layer 106 to a corresponding intra-transistor isolation region 161. Each of the intra-transistor conductive vias 181 is configured to electrically connect, through one or more conductive traces, its corresponding intra-transistor isolation region 161 to a S/D electrode 116 that is a drain electrode of a corresponding transistor.

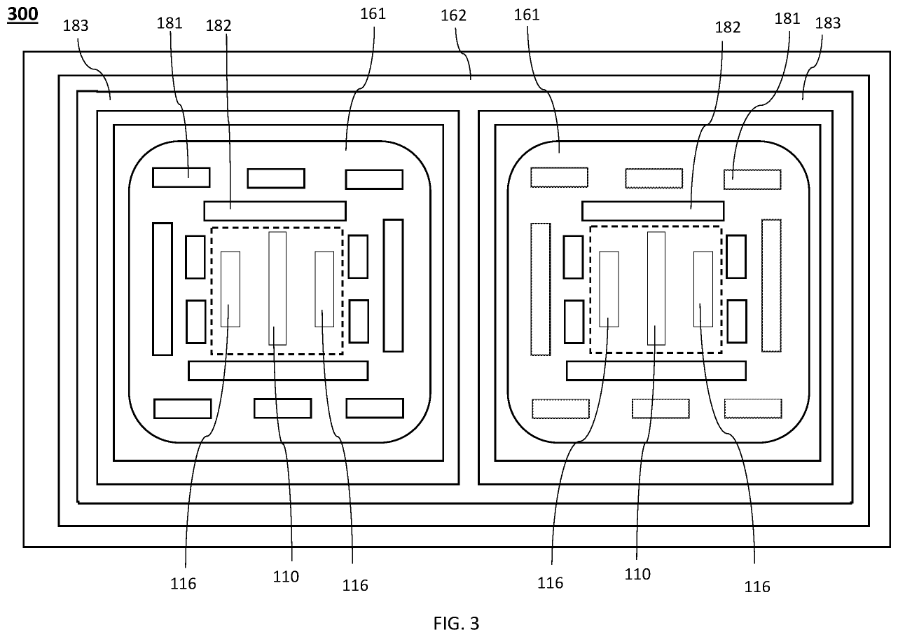

Preferably, the intra-transistor conductive vias 181 are arranged to surround the gate structures 110 and S/D electrodes 116 of the corresponding transistor. In some embodiments, the intra-transistor conductive vias 181 may be formed as a ring enclosing the gate structures 110 and S/D electrodes 116 as shown in FIG. 1. In other embodiments, the intra-transistor conductive vias 181 may be formed as a plurality of separate strips scattered around the gate structures 110 and S/D electrodes 116 as shown in FIG. 3.

In some embodiments, the semiconductor chip 100 may further comprise intra-transistor conductive vias 182 extending from a top surface of the nitride-based epitaxial layer 106 to penetrate and terminate within the epitaxial body layer 108. Each of the intra-transistor conductive vias 182 is configured to electrically connect, through one or more conductive traces, the epitaxial body layer 108 to a S/D electrode 116 that is a source electrode of the corresponding transistor.

Preferably, the intra-transistor conductive vias 182 are arranged to surround the intra-transistor conductive vias 181. In some embodiments, the intra-transistor conductive vias 182 may be formed as a ring enclosing the intra-transistor conductive vias 181 as shown in FIG. 1. In other embodiments, the intra-transistor conductive vias 182 may be formed as a plurality of separate strips scattered around the intra-transistor conductive vias 181 as shown in FIG. 3.

By implementing the intra-transistor conductive vias 182, the epitaxial body layer 108 under the corresponding transistor can be independently biased. Therefore, interference between difference power domains can be avoided.

Referring back to FIGS. 1 and 2. The semiconductor chip 100 may further comprise one or more inter-transistor isolation regions 162, each being located between two neighboring intra-transistor isolation regions 161. The inter-transistor isolation regions 162 may be implanted to have a doping polarity similar to the doping polarity of the substrate 102 and a doping concentration different from the doping concentration of the substrate 102.

In some embodiments, the inter-transistor isolation regions 162 may have a doping concentration higher than the doping concentration of the substrate 102. In other embodiments, the inter-transistor isolation regions 162 may have a doping concentration lower than the doping concentration of the substrate 102.

The semiconductor chip 100 may further comprise one or more inter-transistor conductive vias 183, each extending from a top surface of the nitride-based epitaxial layer 106 to penetrate and terminate within a corresponding inter-transistor isolation region 162. The inter-transistor conductive vias 183 are configured to electrically connect, through one or more conductive traces, the inter-transistor isolation region 162 to a ground GND.

By implementing the inter-transistor isolation regions 162 being connected to ground, the isolation between the transistors can be enhanced and conductivity between substrate 102 and GND can also be improved.

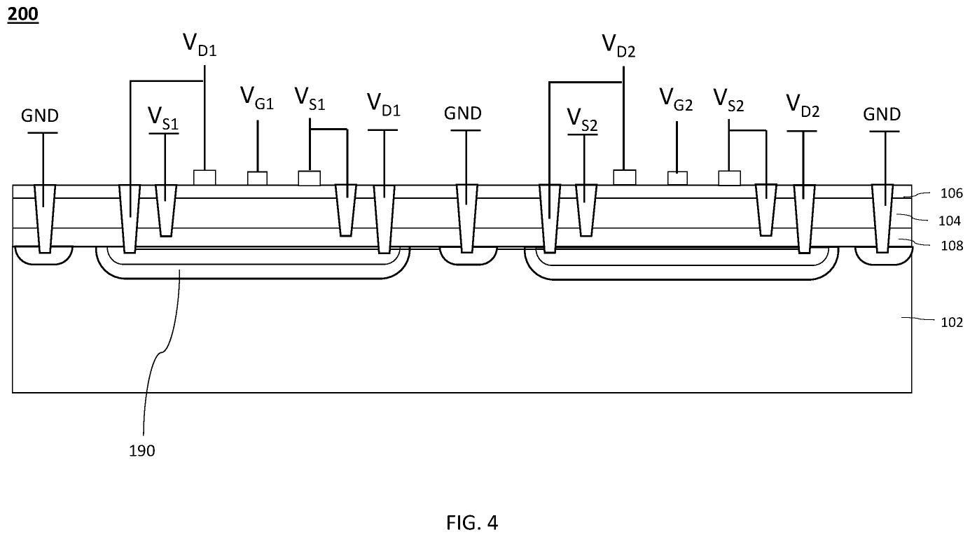

FIG. 4 depicts an exemplary semiconductor chip 200 according to another embodiment of the present invention. The semiconductor chip 200 is similar to semiconductor chip 100 except for that semiconductor chip 200 further comprises an auxiliary isolation layer 190 deposited between the substrate and the intra-transistor isolation region 161.

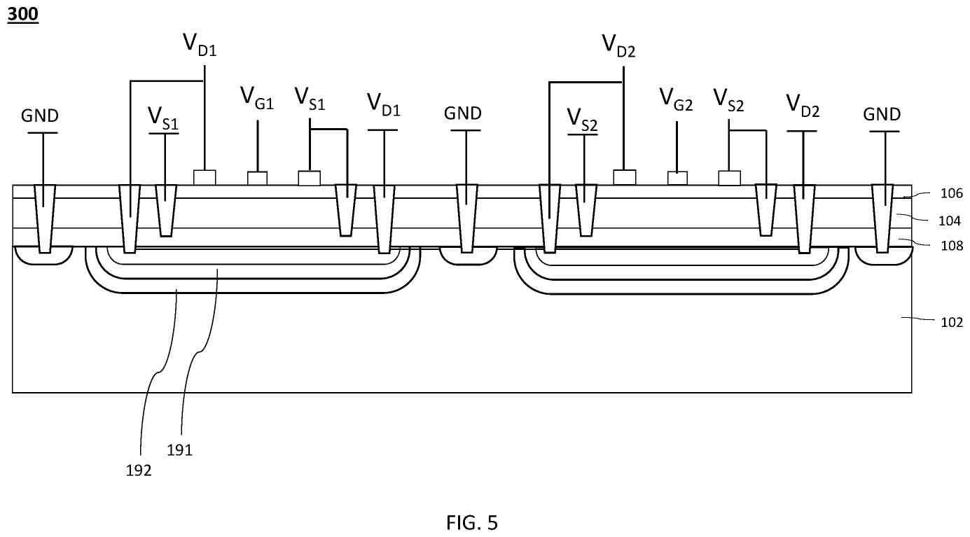

FIG. 5 depicts an exemplary semiconductor chip 300 according to another embodiment of the present invention. The semiconductor chip 300 is similar to semiconductor chip 100 except for that semiconductor chip 300 two auxiliary isolation layers 191 and 192 with opposite doping polarities to form one or more diode structures between the substrate and the intra-transistor isolation region 161.

It should be understood that the semiconductor chips 100, 200 and 300 may further comprise one or more passivation layers (not illustrated) formed above the gate structures and S/D electrodes; and one or more conductive traces (not illustrated) formed between the passivation layers and configured for providing electrical connection from the gate structures and S/D electrodes to external circuits. The one or more conductive traces may be further configured for respectively providing electrical connection from the intra-transistor conductive vias and inter-transistor conductive vias to external circuits.

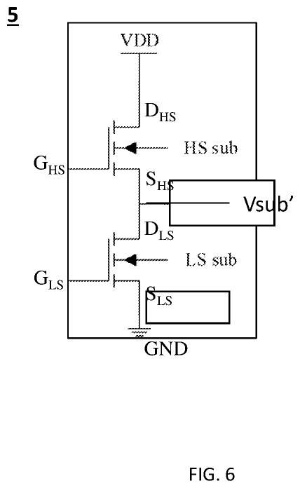

FIG. 6 depicts a circuit diagram of a half-bridge circuit 5 including a higher side (HS) transistor Q_{HS} and a lower side (LS) transistor Q_{LS}. The HS transistor Q_{HS} may have a HS gate terminal G_{HS}, a HS drain terminal DHS and a HS source terminal S_{HS}. The LS transistor Q_{LS} may have a LS gate terminal G_{LS}, a LS drain terminal D_{LS} and a LS source terminal S_{LS}. The HS transistor Q_{HS} and the LS transistor Q_{LS} may be connected in series between a power supply VDD and a ground GND such that the HS drain terminal is connected to the power supply VDD, the LS source terminal is connected to the ground GND, the HS source terminal is connected to the LS drain terminal.

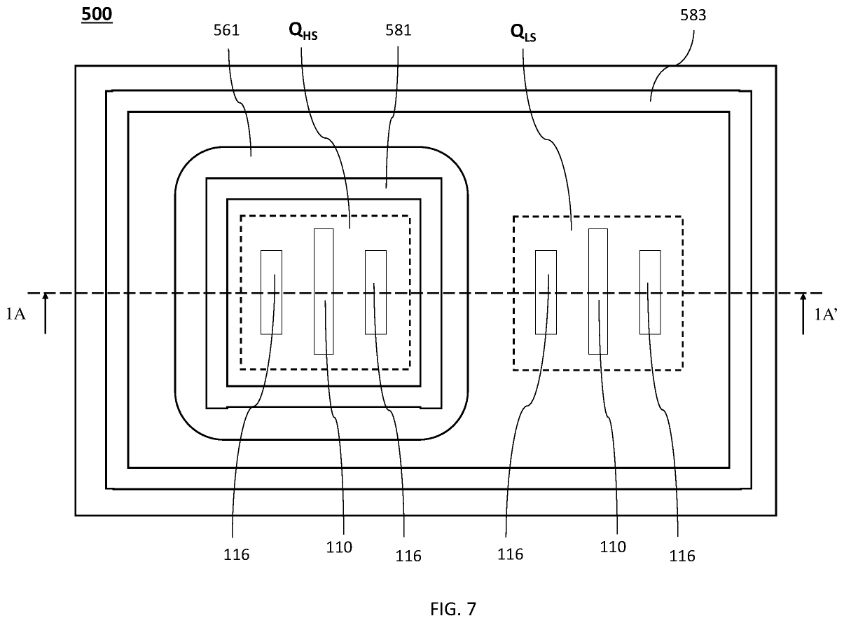

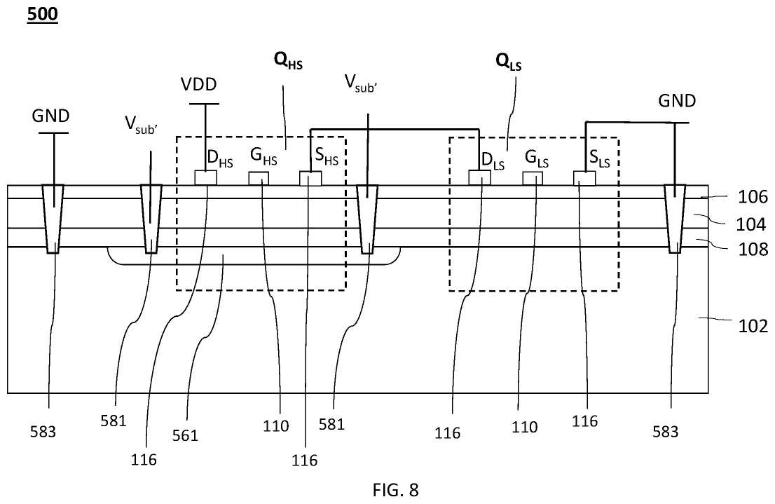

The half-bridge circuit 5 may be integrated into a single semiconductor chip in which a power domain is defined for providing isolation between the HS and LS transistors. FIGS. 7 and 8 depict structure of an exemplary semiconductor chip 500 based on the half-bridge circuit 5. FIG. 7 is a partial layout of the semiconductor chip 500 showing a relationship among some elements that constitute parts of the transistors Q_{HS} and Q_{LS}. FIG. 8 is cross-sectional view taken along a line A-A′ in FIG. 7.

The structure of the semiconductor chip 500 is similar to the structure of the semiconductor chip 100 of FIG. 1 except for that there is isolation region disposed underneath the HS transistor Q_{HS} but no isolation regions disposed underneath the LS transistor Q_{LS}. For conciseness, identical elements of the semiconductor chips 100 and 500 are given the same reference numerals and symbols and will not be further described in details

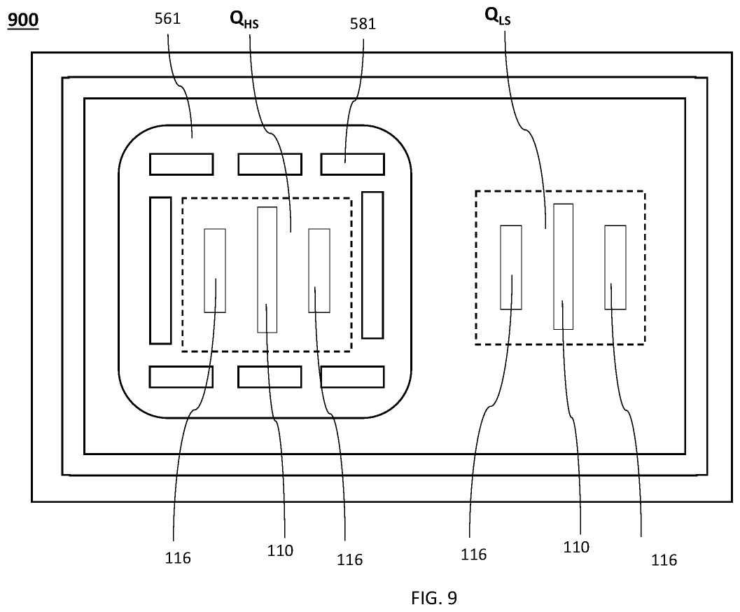

Referring to FIGS. 8 and 9. Similarly, the semiconductor chip 500 may include a substrate 102, an epitaxial body layer 108, a nitride-based semiconductor layer 104, a nitride-based semiconductor layer 106, a plurality of gate electrodes 110, and a plurality of source/drain electrodes 116.

The substrate 102 may be a semiconductor substrate. The epitaxial body layer 108 is disposed over the substrate 102. Preferably, the epitaxial body layer 108 and the substrate 102 are formed of a same material. The nitride-based semiconductor layer 104 may be disposed over the epitaxial body layer 108. The nitride-based semiconductor layer 106 may be disposed on the nitride-based semiconductor layer 104. The gate structures 110 may be disposed on/over/above the nitride-based semiconductor layer 106. The S/D electrodes 116 may be disposed on the nitride-based semiconductor layer 106.

The gate structures 110 may include at least one HS gate structure to act as the HS gate terminal and at least one LS gate structure 110 to act as the LS gate terminal.

In some embodiments, the S/D electrodes 116 may include at least one HS source electrode and at least one HS drain electrode to act as the source terminal and drain terminal of the HS transistor, respectively.

In other embodiments, the S/D electrodes 116 may further include at least one LS source electrode and at least one LS drain electrode to act as the source terminal and drain terminal of the LS transistor, respectively.

The semiconductor chip 500 may further comprise passivation layers (not illustrated) and conductive layers (not illustrated) formed between the passivation layers. The conductive layers are patterned to form conductive traces for providing electrical connection.

The semiconductor chip 500 may further comprise a HS isolation region 561 formed in the substrate 102 and underneath the epitaxial body layer 108. The HS isolation region 561 is disposed underneath the HS transistor to define a power domain for the HS transistor Q_{HS}. Preferably, the HS isolation region 561 is implanted to have a doping polarity opposite to a doping polarity of the substrate 102.

The semiconductor chip 500 may further comprise a HS conductive vias 581 extending from a top surface of the nitride-based epitaxial layer 106 to the HS isolation region 561. The HS conductive vias 581 is configured to electrically connect, through one or more conductive traces, the HS isolation region 561 to the source terminal of the HS transistor Q_{HS}. As such, the HS isolation region 561 can have a potential the same as the source terminal of the HS transistor Q_{HS} and act as an effective substrate for the HS transistor Q_{HS} such that the back-gate effect due to the potential difference between substrate and source can be eliminated.

Preferably, the HS conductive vias 581 are arranged to surround the gate structures 110 and S/D electrodes 116 of the HS transistor Q_{H}S. In some embodiments, the HS conductive vias 581 may be formed as a ring enclosing the gate structures 110 and S/D electrodes 116 as shown in FIG. 7. In other embodiments, the HS conductive vias 581 may be formed as a plurality of separate strips scattered around the gate structures 110 and S/D electrodes 116 as shown in FIG. 9.

The semiconductor chip 100 may further comprise one or more inter-transistor conductive vias 583, each extending from a top surface of the nitride-based epitaxial layer 106 to penetrate and terminate within the substrate 102. The inter-transistor conductive vias 183 are configured to electrically connect, through one or more conductive traces, the substrate to a ground GND.

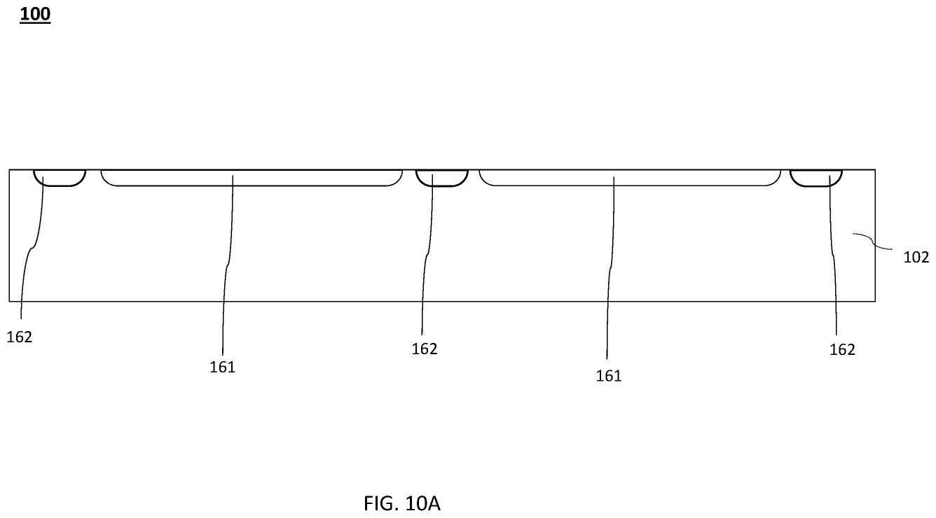

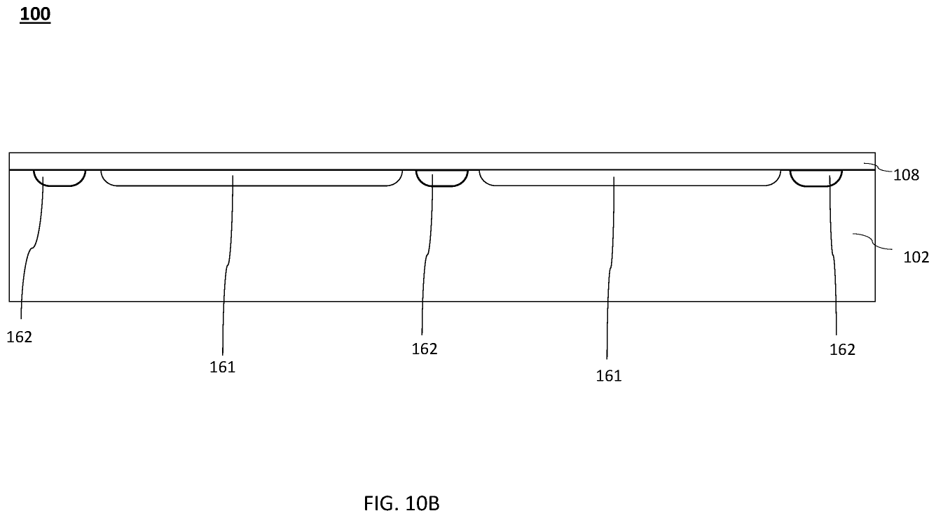

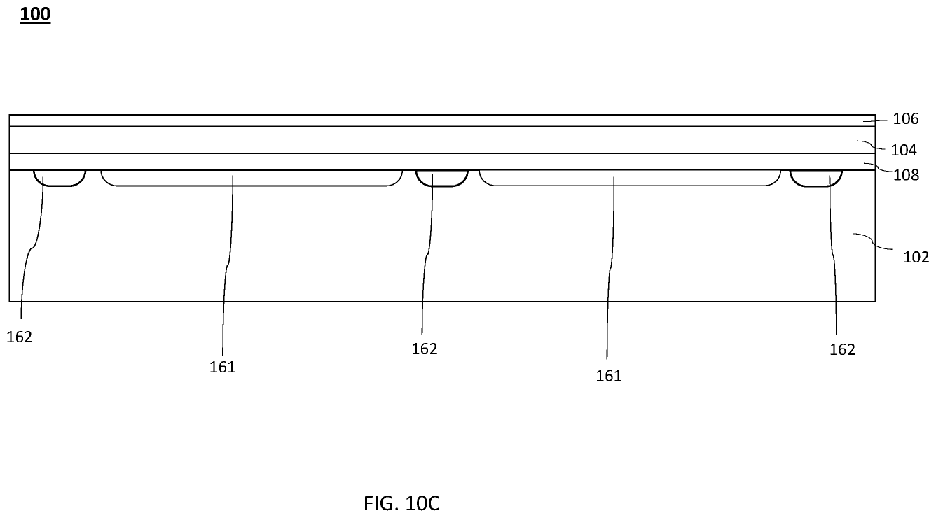

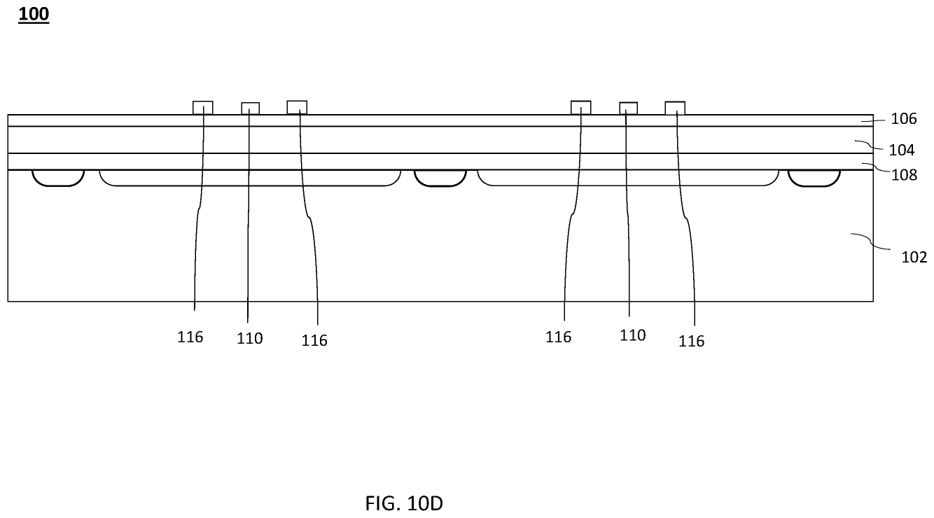

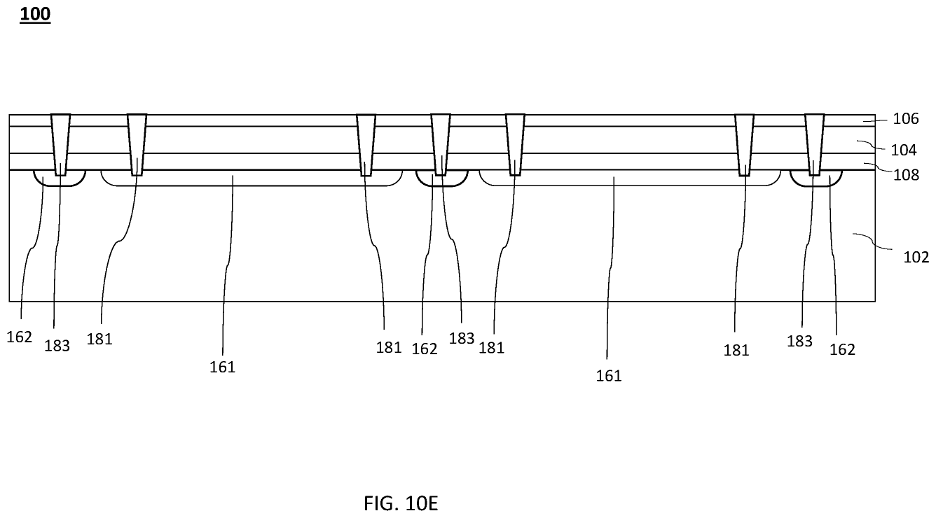

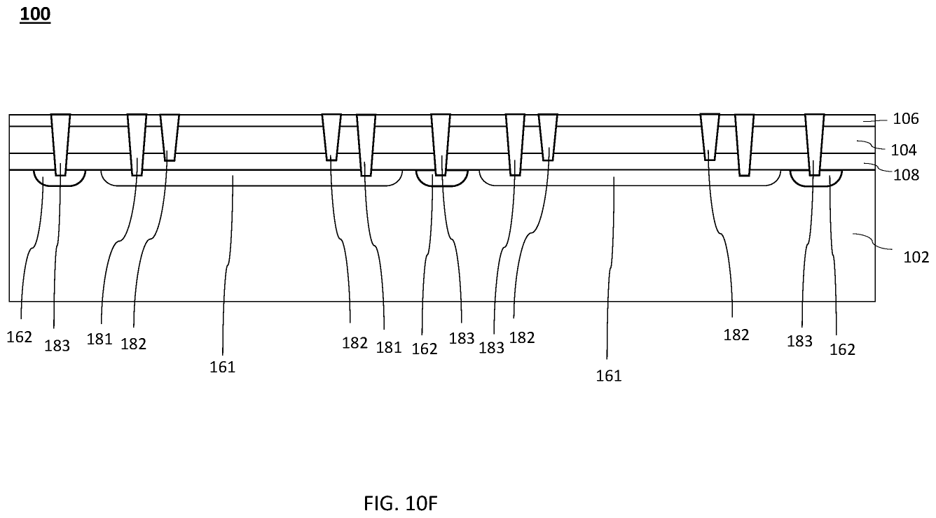

Different stages of a method for manufacturing the semiconductor chip according to the present invention are shown in FIGS. 10A-10F and described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes. The process for forming the passivation layers serving as a planarization layer generally includes a chemical mechanical polish (CMP) process. The process for forming the conductive vias generally includes forming vias in a passivation layer and filling the vias with conductive materials. The process for forming the conductive traces generally includes photolithography, exposure and development, etching, other suitable processes, or combinations thereof.

Referring to FIG. 10A, substrate 102 (with typical thickness about 0.7 to 1.2 mm) is provided, and isolation regions 161/162 are implanted in a surface of the substrate. The isolation regions can be formed by performing a Si oxidation on substrate 102, developing a photo-resist pattern definition over substrate 102 using photo lithography, exposing substrate 102 to a dopant, such as high energy boron atoms, using an implanter, stripping away the remaining photo-resist, annealing the wafer at high temperatures (e.g., 1100° C.) for an appropriate duration (e.g., 3 hours), and then stripping any surface oxide by immersion in hydrogen-fluoride containing acid.

Referring to FIG. 10B, an epitaxial body layer 108 can be formed above the substrate 102 using nucleation and growth processes. The epitaxial body layer 108 may be composed of one or more sublayers of Si materials and may have a thickness in a range of about 2 μm to about 7 μm.

Referring to FIG. 10C. Two nitride-based semiconductor layers 104 and 106 can then be formed on the epitaxial body layer 108 using the above-mentioned deposition techniques. The nitride-based semiconductor layer 104 serves as a primary current channel and the nitride-based semiconductor layer 106 serves as a barrier layer. As a result, A 2DEG region is formed adjacent to a heterojunction interface between the nitride-based semiconductor layer 104 and the nitride-based semiconductor layer 106. Formation of nitride-based semiconductor layers 104 and 106 can include depositing a layer of GaN or InGaN material typically about 0.01 to about 0.5 μm in thickness to form current conducting region, and depositing a layer of material composed of AlGaN where the Al fraction (which is the content of Al such that Al fraction plus Ga fraction equals 1) is in a range of about 0.1 to about 1.0 and the thickness is in a range between about 0.01 and about 0.03 μm to form barrier layer.

Referring to FIG. 10D. One or more gate structure 110 and S/D electrodes 116 are then formed over the nitride-based semiconductor layer 106. Gate structure 110 can be formed, for example, by depositing p-type GaN material on a surface of nitride-based semiconductor layer 106, etching the gate structure 110 from the p-type GaN material, and forming a refractory metal contact such as tantalum (Ta), titanium (Ti), titanium nitride (TiN), tungsten (W), or tungsten silicide (WSi₂) over the GaN material. It should be understood that other known methods and materials for providing a gate structure 110 can also be used. S/D electrodes 116 can be formed from any known ohmic contact metals, such as Ti and/or Al, along with a capping metal such as Ni, Au, Ti or TiN. The metal and gate layer are each preferably about 0.01 to about 1.0 μm in thickness, and then annealed at high temperature, such as 800° C. for 60 seconds.

Referring to FIG. 10E. The conductive vias 181/183 are then formed to extend from the nitride-based semiconductor layer 106 to the isolation regions. Openings may be fabricated by covering nitride-based semiconductor layer 106 with SiO₂ and a photo-resist everywhere except at the site of the vias 181/183, and then exposing the covered device to a high energy plasma in an etch chamber. The high energy plasma typically contains chlorine based gases, such as BCl₃ or Cl₂, and is generated through high frequency oscillating fields produced within the etch chamber. After etching through from the nitride-based semiconductor layer 106 to the isolation regions, the photo-resist is stripped off using chemical strippers, oxygen plasma, or combinations of these techniques. TiN and Al can be deposited into the openings to form the conductive vias 181/183, with the TiN material forming an outer layer along the walls of openings with a thickness in a range of about 100-200 Å, and the Al material forming the interior of vias 181/183 having a thickness in a range of about 1-5 um. The TiN outer layer promotes adhesion of an Al material.

Referring to FIG. 10F. The conductive vias 182 are then formed to extend from the nitride-based semiconductor layer 106 to the epitaxial body layer 108. The process for forming vias 182 is similar to that for forming vias 181/183 except for that the opens are etched through from the nitride-based semiconductor layer 106 to the epitaxial body layer 108.

Although it is demonstrated in this embodiment that conductive vias 181/183 are formed before conductive vias 182, it should be understood that conductive vias 182 may also be formed before conductive vias 181/183, depending on the actual fabrication procedures.

It should also be understood that passivation layers and routing (conductive) layers may then be deposited and etched to form connections between the conductive vias, gate structures and electrodes 116 with external circuits.

The embodiments were chosen and described in order to best explain the principles of the invention and its practical application, thereby enabling others skilled in the art to understand the invention for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the figures. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor integrated circuit chip including one or more transistors, comprising:
a substrate;
one or more intra-transistor isolation regions formed in a surface of the substrate for defining one or more power domain for the one or more transistors respectively;
an epitaxial body layer disposed over the substrate and the intra-transistor isolation regions;
a first nitride-based epitaxial layer disposed above the epitaxial body layer;
a second nitride-based epitaxial layer disposed on the first nitride-based epitaxial layer and having a bandgap greater than a bandgap of the first nitride-based epitaxial layer;
one or more gate structures and one or more source/drain electrodes disposed above the second nitride-based epitaxial layer;
one or more first intra-transistor conductive vias extending from a top surface of the second nitride-based epitaxial layer to a corresponding intra-transistor isolation region;
wherein each of the transistors includes at least one gate structure and at least one pair of source/drain electrodes;
wherein the epitaxial body layer and the substrate are formed of a same material; and
wherein each of the one or more intra-transistor isolation regions is implanted to have a doping polarity opposite to a doping polarity of the substrate.

2. The nitride-based semiconductor integrated circuit chip according to claim 1,
wherein:
the one or more transistors comprise:
a higher side (HS) transistor having a HS source electrode and a HS drain electrode; and
a lower side (LS) transistor having a LS source electrode and a LS drain electrode;
the one or more intra-transistor isolation regions comprise a HS isolation region disposed underneath the HS transistor; and
the one or more first intra-transistor conductive vias include a HS conductive via extending from the top surface of the second nitride-based epitaxial layer to the HS isolation region to electrically connect the HS isolation region to the HS source electrode and the LS drain electrode.

3. The nitride-based semiconductor integrated circuit chip according to claim 1, further comprising one or more second intra-transistor conductive vias extending from a top surface of the second nitride-based epitaxial layer to penetrate and terminate within the epitaxial body layer;
wherein:
each of the one or more first intra-transistor conductive vias is configured to electrically connect an intra-transistor isolation region to a drain electrode of a corresponding transistor; and
each of the one or more second intra-transistor conductive vias is configured to electrically connect the epitaxial body layer to a source electrode of a corresponding transistor.

4. The nitride-based semiconductor integrated circuit chip according to claim 1, further comprising one or more second intra-transistor conductive vias extending from a top surface of the second nitride-based epitaxial layer to penetrate and terminate within the epitaxial body layer;
wherein:
each of the one or more first intra-transistor conductive vias is configured to electrically connect an intra-transistor isolation region to a source electrode of a corresponding transistor; and
each of the one or more second intra-transistor conductive vias is configured to electrically connect the epitaxial body layer to a drain electrode of a corresponding transistor.

5. The nitride-based semiconductor integrated circuit chip according to claim 1, further comprising:
one or more inter-transistor isolation regions, each being located between two neighboring intra-transistor isolation regions and implanted to have a doping polarity similar to the doping polarity of the substrate and a doping concentration different from the doping concentration of the substrate; and
one or more inter-transistor conductive vias, each extending from a top surface of the second nitride-based epitaxial layer to penetrate and terminate within a corresponding inter-transistor isolation region and configured to electrically connecting the inter-transistor isolation region to a ground.

6. The nitride-based semiconductor integrated circuit chip according to claim 1, further comprising one or more auxiliary isolation layers deposited between the substrate and the intra-transistor isolation region.

7. The nitride-based semiconductor integrated circuit chip according to claim 6, the one or more auxiliary isolation layers are alternatively arranged with opposite doping polarities to form one or more diode structures between the substrate and the intra-transistor isolation region.

8. The nitride-based semiconductor integrated circuit chip according to claim 1, wherein the substrate and the epitaxial body layer are made of silicon.

9. The nitride-based semiconductor integrated circuit chip according claim 1, further comprising:
one or more passivation layers formed above the gate structures and S/D electrodes; and
one or more conductive traces formed between the passivation layers and configured for providing electrical connection from the gate structures and S/D electrodes to external circuits.

10. The nitride-based semiconductor integrated circuit chip according to claim 1, wherein the one or more conductive traces are further configured for respectively providing electrical connection from the intra-transistor conductive vias and inter-transistor conductive vias to external circuits.

11. A method for manufacturing a nitride-based semiconductor integrated circuit chip including one or more transistors, comprising:
providing a substrate;
forming one or more intra-transistor isolation regions and one or more inter-transistor isolation regions in a surface of the substrate and implanting the one or more intra-transistor isolation regions to have a doping polarity opposite to a doping polarity of the substrate;
forming a epitaxial body layer over the substrate and the intra-transistor isolation regions;
forming a first nitride-based epitaxial layer over the epitaxial body layer;
forming a second nitride-based epitaxial layer on the first nitride-based epitaxial layer;
integrating one or more nitride-based semiconductor devices by:
forming one or more gate structures over the second nitride-based epitaxial layer such that each gate structure is aligned vertically with a respective intra-transistor isolation region;
forming one or more pairs of source/drain (S/D) electrodes over the second nitride-based epitaxial layer, such that each gate structure is located between a respective pair of S/D electrodes; and
forming one or more first intra-transistor conductive vias, each extending from a top surface of the second nitride-based epitaxial layer to penetrate and terminate within the intra-transistor isolation region;
wherein each of the transistors includes at least one gate structure and at least one pair of source/drain electrodes; and
wherein the epitaxial body layer and the substrate are formed of a same material;
wherein each of the one or more intra-transistor isolation regions is implanted to have a doping polarity opposite to a doping polarity of the substrate.

12. The method according to claim 11, further comprising:
forming a higher side (HS) transistor having a HS source electrode and a HS drain electrode; and
forming a lower side (LS) transistor having a LS source electrode and a LS drain electrode;
forming a HS isolation region disposed underneath the HS transistor; and
forming a HS conductive via extending from the top surface of the second nitride-based epitaxial layer to the HS isolation region to electrically connect the HS isolation region to the HS source electrode and the LS drain electrode.

13. The method according to claim 11, further comprising:
forming one or more second intra-transistor conductive vias extending from a top surface of the second nitride-based epitaxial layer to penetrate and terminate within the epitaxial body layer;
configuring each of the one or more first intra-transistor conductive vias to electrically connect an intra-transistor isolation region to a drain electrode of a corresponding transistor; and
configuring each of the one or more second intra-transistor conductive vias to electrically connect the epitaxial body layer to a source electrode of a corresponding transistor.

14. The method according to claim 11, further comprising:
forming one or more second intra-transistor conductive vias extending from a top surface of the second nitride-based epitaxial layer to penetrate and terminate within the epitaxial body layer;
configuring each of the one or more first intra-transistor conductive vias to electrically connect an intra-transistor isolation region to a source electrode of a corresponding transistor; and
configuring each of the one or more second intra-transistor conductive vias to electrically connect the epitaxial body layer to a drain electrode of a corresponding transistor.

15. The method according to claim 11, further comprising:
forming one or more inter-transistor isolation regions between two neighboring intra-transistor isolation regions and implanting the one or more inter-transistor isolation regions to have a doping polarity similar to the doping polarity of the substrate and a doping concentration different from the doping concentration of the substrate; and
forming one or more inter-transistor conductive vias extending from a top surface of the second nitride-based epitaxial layer to penetrate and terminate within a corresponding inter-transistor isolation region and configuring the one or more inter-transistor conductive vias to electrically connecting the inter-transistor isolation region to a ground.

16. The method according to claim 11, further comprising forming one or more auxiliary isolation layers between the substrate and the intra-transistor isolation region.

17. The method according to claim 16, further comprising arranging the one or more auxiliary isolation layers alternatively with opposite doping polarities to form one or more diode structures between the substrate and the intra-transistor isolation region.

18. The method according to claim 11, wherein the substrate and the epitaxial body layer are made of silicon.

19. The method according to claim 11, further comprising:
forming one or more passivation layers above the gate structures and S/D electrodes; and
forming one or more conductive traces between the passivation layers and configured for providing electrical connection from the gate structures and S/D electrodes to external circuits.

20. The method according to claim 11, further comprising configuring the one or more conductive traces for respectively providing electrical connection from the intra-transistor conductive vias and inter-transistor conductive vias to external circuits.
